(19) United States
(12) Patent Application Publication
(10) Pub. No.: US 2017/0115340 A1
(43) Pub. Date: Apr. 27, 2017

(54) VOLTAGE CALIBRATION CIRCUIT CAPABLE OF UPDATING VOLTAGE TO BE CALIBRATED AUTOMATICALLY

(71) Applicant: Powerchip Technology Corporation, Hsinchu (TW)

(72) Inventor: Hung-Ta Sung, Hsinchu City (TW)

(21) Appl. No.: 14/989,779

(22) Filed: Jan. 6, 2016

(30) Foreign Application Priority Data
Oct. 27, 2015 (TW) 104135202

(51) Int. Cl. G01R 31/28; H03K 19/21; G05F 3/02; H03K 5/24

(52) U.S. Cl. CPC G01R 31/2884; H03K 5/24; H03K 19/21; G05F 3/02

(57) ABSTRACT

A voltage calibration circuit includes a voltage output circuit, an amplifier, a notification circuit, and a built-in self-test circuit. The voltage output circuit selects a first voltage source to output an output voltage according to a selection signal. Two input terminals of the amplifier are for receiving the output voltage and a reference voltage corresponding to the first voltage source respectively. The notification circuit outputs a notification signal according to the reference voltage, a voltage at an output terminal of the amplifier and an indication voltage. The indication voltage and the output voltage have a fixed voltage difference. The built-in self-test circuit updates the selection signal according to the notification signal so that the voltage output circuit can select a second voltage source accordingly.

### BACKGROUND OF THE INVENTION

1. Field of the Invention

This invention is related to a voltage calibration circuit, and more particularly, to a voltage calibration circuit that is capable of updating the output voltage to be calibrated automatically.

2. Description of the Prior Art

Since complexity of integrated circuits has increased over time, the system may require a variety of voltage sources to drive different functional elements within one integrated circuit. However, after complicated manufacturing processes, semiconductor components may have different characteristics from each other, which makes the voltage generated by a voltage source be different from its target voltage. For example, a voltage source designed to supply 1.5V may output 1.2V instead when using default parameters due to variations in the manufacturing process. To avoid skewed operations of functional elements caused by the mismatch of voltages, the parameters of the voltage sources have to be fine-tuned after the manufacturing process so as to bring their output voltages closer to the target values.

To shorten the time for calibration, the integrated circuit of prior art usually includes a built-in self-test (BIST) circuit, which can be connected to an external tester. The tester can provide the target voltage required by the integrated circuit. The BIST circuit can compare the target voltage and the voltage outputted by the voltage source, and can keep adjusting the parameters of the voltage source until the voltage outputted by the voltage source is close enough to the target voltage. Afterward, the adjusted parameters can be used as the parameters for the voltage source to output the wanted voltage. During the testing process, the tester and the BIST circuit should be aware of the statuses from each other to perform the corresponding operations. For example, the tester needs to know whether the BIST circuit has already completed the calibration so that the tester can provide a next target voltage, and the BIST circuit needs to know whether the tester has already updated the target voltage so that the BIST circuit can move on to a next voltage source to be calibrated. Therefore, the integrated circuit usually reserves a bus for communication between these two circuits. In the prior art, the bus for such communication may require more than 8 pins. Since the package used by an integrated circuit may partly depend on the number of pins, the number of pins of the integrated circuit can significantly affect the area required by the integrated circuit. Therefore, how to reduce the pins required by the communication between the tester and the BIST circuit has become a critical issue to be resolved.

### SUMMARY OF THE INVENTION

One embodiment of the present invention discloses a voltage calibration circuit. The voltage calibration circuit includes a voltage output circuit, a first amplifier, a notification circuit, and a built-in self-test circuit. The voltage output circuit comprises a plurality of voltage sources to be calibrated, and can select a first voltage source from the plurality of voltage sources to output an output voltage to be calibrated according to a selection signal. The first amplifier has a first input terminal configured to receive the output voltage, a second input terminal configured to receive a reference voltage corresponding to the first voltage source, and an output terminal. The notification circuit is coupled to the output terminal of the first amplifier. The notification circuit can output a notification signal according to an indication voltage, the reference voltage, and a voltage at the output terminal of the first amplifier. The built-in self-test circuit is coupled to the notification circuit, the first amplifier, and the voltage output circuit, and the built-in self-test circuit can update the selection signal according to the notification signal so as to enable the voltage output circuit to select a second voltage source from the plurality of voltage sources accordingly.

One embodiment of the present invention discloses a voltage calibration system. The voltage calibration system includes a voltage calibration circuit and a test circuit. The voltage calibration circuit includes a voltage output circuit, a first amplifier, a notification circuit, and a built-in self-test circuit. The voltage output circuit comprises a plurality of voltage sources to be calibrated, and can select a first voltage source from the plurality of voltage sources to output an output voltage to be calibrated according to a selection signal. The first amplifier has a first input terminal configured to receive the output voltage, a second input terminal configured to receive a reference voltage corresponding to the first voltage source, and an output terminal. The notification circuit is coupled to the output terminal of the first amplifier. The notification circuit can output a notification signal according to an indication voltage, the reference voltage, and a voltage at the output terminal of the first amplifier. The built-in self-test circuit is coupled to the notification circuit, the first amplifier, and the voltage output circuit. The built-in self-test circuit can output a completion signal according to the voltage at the output terminal of the first amplifier and update the selection signal according to the notification signal so as to enable the voltage output circuit to select a second voltage source from the plurality of voltage sources accordingly. The test circuit can provide the reference voltage corresponding to the first voltage source, and adjust the reference voltage according to the completion signal. The adjusted reference voltage is corresponding to the second voltage source.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a voltage calibration circuit according to one embodiment of the present invention.

FIG. 2 shows a voltage calibration circuit according to another embodiment of the present invention.

FIG. 3 shows a voltage calibration system according to one embodiment of the present invention.

### DETAILED DESCRIPTION

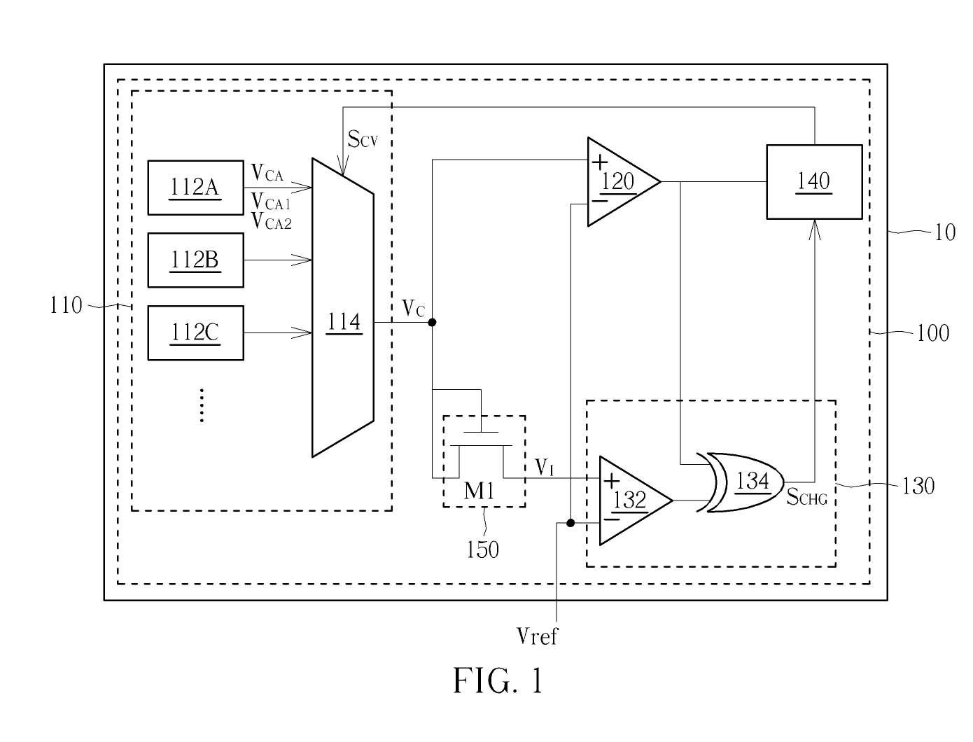

FIG. 1 shows a voltage calibration circuit 100 according to one embodiment of the present invention. In FIG. 1, the voltage calibration circuit 100 is disposed inside a chip 10 for calibrating the voltage sources required by the chip 10. The voltage calibration circuit 100 includes a voltage output circuit 110, a first amplifier 120, a notification circuit 130, and a built-in self-test (BIST) circuit 140.

The voltage output circuit 110 includes a plurality of voltage sources 112A, 112B, and 112C. The voltage sources 112A, 112B, and 112C can provide different voltages required by the chip 10. For example, the voltage source 112A can provide a target voltage of 1.5V, the voltage source 112B can provide a target voltage of 1.2V, and the voltage source 112C can provide a target voltage of 1.8V. Since the characteristics of the voltage sources 112A, 112B, and 112C may not be the same as expected due to the semiconductor manufacturing process, the voltages outputted by the voltage sources 112A, 112B, and 112C may be different from their target voltages when using default parameters. Therefore, calibration is required.

The voltage output circuit 110 can select a voltage source from the voltage sources 112A, 112B, and 112C to be calibrated according to a selection signal S_{CV}. For example, in FIG. 1, the voltage output circuit 110 includes a multiplexer 114. The multiplexer 114 is coupled to the voltage sources 112A, 112B, and 112C, and can establish an electrical connection between a voltage source of the voltage sources 112A, 112B, and 112C and an output terminal of the voltage output circuit 110 to output the output voltage V_{C} to be calibrated. For example, when the voltage source 112A is chosen to be calibrated, that is, when selecting the voltage source 112A as a first voltage source to be calibrated, the selection signal S_{CV} can enable the multiplexer 114 to establish the electrical connection between the voltage source 112A and the output terminal of the voltage output circuit 110.

The first amplifier 120 has a first input terminal, a second input terminal, and an output terminal. The first input terminal of the first amplifier 120 can receive the output voltage V_{C} to be calibrated, the second input terminal of the first amplifier 120 can receive a reference voltage V_{ref} corresponding to the first voltage source 112A, in this case, the reference voltage V_{ref} is 1.5V. In some embodiments of the present invention, the reference voltage V_{ref} is provided by an external circuit.

The BIST circuit 140 is coupled to the first amplifier 120 and the voltage output circuit 110, and can calibrate the voltage output circuit 110 according to a voltage at the output terminal of the first amplifier 120. In other words, when the BIST circuit 140 needs to calibrate the voltage source 112A, the BIST circuit 140 can output the selection signal S_{CV} corresponding to the voltage source to be calibrated first so that the voltage output circuit 110 can output the output voltage V_{C} to be calibrated according to the voltage V_{CA} outputted by the voltage source 112A.

The voltage source 112A can output the voltage V_{CA} according to its default parameters first, and the BIST circuit 140 can derive the relation between voltage V_{C} and the reference voltage V_{ref} according to the voltage at the output terminal of the first amplifier 120. In some embodiments of the present invention, the first input terminal of the first amplifier 120 can be a positive terminal, and the second input terminal of the first amplifier 120 can be a negative terminal. In this case, when the voltage V_{C} is greater than the reference voltage V_{ref}, the voltage at the output terminal of the first amplifier 120 would be at a high voltage level, and when the voltage V_{C} is smaller than the reference voltage V_{ref}, the voltage at the output terminal of the first amplifier 120 would be at a low voltage level.

For example, when the voltage V_{C} is 1.32 and the reference voltage V_{ref} is 1.5V, the voltage at the output terminal of the first amplifier 120 is at the low voltage level. At this time, the BIST circuit 140 can control the voltage output circuit 110 to adjust the parameters of the voltage source 112A so as to cause the voltage source 112A to output a higher voltage V_{CA1}. If the voltage V_{CA1} is 1.44V, for example, since the voltage V_{CA1} is still smaller than the reference voltage V_{ref}, the BIST circuit 140 can keep adjusting the parameters of the voltage source 112A to cause the voltage source 112A to output an even higher voltage V_{CA2}, which may be 1.56V, for example. Namely, the voltage source 112A can sequentially output a plurality of voltages V_{CA}, V_{CA1}, and V_{CA2} to be calibrated according to the control of the BIST circuit 140.

Since the voltage V_{CA2} is greater than V_{ref}, the voltage at the output terminal of the first amplifier 120 would change to the high voltage level. The BIST circuit 140 can determine that the voltage source 112A has completed calibration when the voltage at the output terminal of the first amplifier changes from the low voltage level to the high voltage level, and BIST circuit 140 can save the parameters at that time as calibrated parameters of the voltage source 112A. When the voltage source 112A uses the calibrated parameters, the voltage outputted by the voltage source 112A would be closer to its target voltage than the voltage it generates before calibration.

In some embodiments of the present invention, the BIST circuit 140 can also determine that the voltage source 112A has completed calibration when the voltage at the output terminal of the first amplifier 120 changes from the high voltage level to the low voltage level, when the voltage at the output terminal of the first amplifier 120 changes, or when the voltage V_{C} is close enough to the reference voltage V_{ref}.

After the calibration of the voltage source 112A is completed, the BIST circuit 140 can select a next voltage source from the voltage output circuit 110 to be calibrated. However, before the calibration of the next voltage source, the BIST circuit 140 must confirm whether the reference voltage V_{ref} has been changed to a target voltage of the next voltage source, so that the BIST circuit 140 can move on and repeat the aforesaid calibration process. In this case, the BIST circuit 140 can be informed if the reference voltage V_{ref} has been updated properly according to the notification signal S_{CHG} outputted by the notification circuit 130.

The notification circuit 130 is coupled to the output terminal of the first amplifier 120. The notification circuit 130 can receive the indication voltage V_{I}, the reference voltage V_{ref}, and the voltage at the output terminal of the first amplifier 120, and can output the notification signal S_{CHG} according to the indication voltage V_{I}, the reference voltage V_{ref}, and the voltage at the output terminal of the first amplifier 120. The indication voltage V_{I} and the output voltage V_{C} have a first fixed voltage difference ΔV₁, ex., 0.2V.

In FIG. 1, the notification circuit 130 includes a second amplifier 132 and an exclusive OR (XOR) gate 134. The second amplifier 132 has a first input terminal, a second input terminal and an output terminal. The first input terminal of the second amplifier 132 can receive the indication voltage V_{I}, and the second input terminal of the second amplifier 132 can receive the reference voltage V_{ref}. In the present embodiment, the first input terminal of the second amplifier 132 is a positive terminal, and the second input terminal of the second amplifier 132 is a negative terminal. The exclusive OR gate 134 has a first input terminal, a second input terminal, and an output terminal. The first input terminal of the exclusive OR gate 134 is coupled to the output terminal of the first amplifier 120, the second input terminal of the exclusive OR gate 134 is coupled to the output terminal of the second amplifier 132, and the output terminal of the exclusive OR gate 134 can output the notification signal S_{CHG}.

If the target voltage of the first voltage source and the target voltage of the second voltage source (the next voltage source to be calibrated) have a second fixed voltage difference ΔV₂, then the second fixed voltage difference ΔV₂ should be greater than the first fixed voltage difference ΔV₁ between the output voltage V_{C} and the indication voltage V_{I}. In addition, if two of the voltages V_{CA}, V_{CA1}, and V_{CA2} have a third fixed voltage difference ΔV₃, ex. 0.12V in the aforesaid example, then the third fixed voltage difference ΔV₃ should be no greater than the first fixed voltage difference ΔV₁.

Table 1 shows the reference voltage V_{ref}, the output voltage V_{C}, the indication voltage V_{I}, voltages at the output terminals of the amplifier 120 and 132, and voltage of the notification signal S_{CHG} in different periods after the voltage source 112A completes calibration.

TABLE 1

| | | | | output | output | |
|---|---|---|---|---|---|---|
| | | | | terminal | terminal of | notifi- |
| | reference | output | indication | of the first | the second | cation |
| | voltage | voltage | voltage | amplifier | amplifier | signal |
| | V_{ref} | V_{C} | V_{I} | 120 | 132 | S_{CHG} |
| Period | 1.5 V | 1.56 V | 1.36 V | H | L | H |
| T1 | | | | | | |
| Period | 1.2 V | 1.56 V | 1.36 V | H | H | L |
| T2 | | | | | | |

According to Table 1, during period T1, the voltage source 112A has finished calibration but the reference voltage V_{ref} has not been updated yet. The reference voltage V_{ref} remains as the target voltage 1.5V of the voltage source 112A and the output voltage V_{C} is at 1.56V. In this case, the voltage at the output terminal of the first amplifier 120 is at the high voltage level H. Also, since the indication voltage V_{I} and the output voltage V_{C} have the first fixed voltage difference ΔV₁, that is, the indication voltage V_{I} is at 1.36V, which is smaller than the reference voltage V_{ref}, the voltage at the output terminal of the second amplifier 132 is at the low voltage level L. Therefore, the voltage at the output terminal of the exclusive OR gate 134 is at the high voltage level H, namely, the notification signal S_{CHG} is at the high voltage level H.

During period T2, the voltage source 112A has finished calibration, and the reference voltage V_{ref} has been updated to the target voltage of the next voltage source to be calibrated. For example, if the voltage source 112B is the second voltage source to be calibrated next, the reference voltage V_{ref} would be updated to the target voltage 1.2V of the voltage source 112B. In this case, since the BIST circuit 140 has not updated the selection signal S_{CV} yet, the output voltage V_{C} would remain at the voltage V_{CA2} outputted from the voltage source 112A, that is, 1.56V. Therefore, the voltage at the output terminal of the first amplifier 120 remains at the high voltage level H.

In addition, the second fixed voltage difference ΔV₂ is greater than the first fixed voltage difference ΔV₁, that is, the second fixed voltage difference ΔV₂ between the target voltage 1.5V of the voltage source 112A and the target voltage 1.2V of the voltage source 112B is 0.3V, which is greater than the first fixed voltage difference ΔV₁, which is 0.2V. Therefore, the indication voltage V_{I} would be greater than the updated reference voltage V_{ref}, which makes the voltage at the output terminal of the second amplifier 132 to be at the high voltage level H, and further makes the voltage at the output terminal of the exclusive OR gate 134 to be at the low voltage level L. Namely, the notification signal S_{CHG} would be at the low voltage level L.

Table 2 shows the reference voltage V_{ref}, the output voltage V_{C}, the indication voltage V_{I}, voltages at the output terminals of the amplifier 120 and 132, and voltage of the notification signal S_{CHG} in different periods after the voltage source 112A completes calibration according to another embodiment.

TABLE 2

| | | | | output | output | |
|---|---|---|---|---|---|---|
| | | | | terminal | terminal of | notifi- |
| | reference | output | indication | of the first | the second | cation |
| | voltage | voltage | voltage | amplifier | amplifier | signal |
| | V_{ref} | V_{C} | V_{I} | 120 | 132 | S_{CHG} |
| Period | 1.5 V | 1.56 V | 1.36 V | H | L | H |
| T1 | | | | | | |
| Period | 1.8 V | 1.56 V | 1.36 V | L | L | L |
| T3 | | | | | | |

According to Table 1, during period T1, the voltage source 112A has finished calibration, however, the reference voltage V_{ref} remains at the target voltage 1.5V of the voltage source 112A and the output voltage V_{C} is at 1.56V. In this case, the voltage at the output terminal of the first amplifier 120 is at the high voltage level H. Also, since the indication voltage V_{I} is smaller than the reference voltage V_{ref}, the voltage at the output terminal of the second amplifier 132 is at the low voltage level L. Therefore, the voltage at the output terminal of the exclusive OR gate 134 is at the high voltage level H, namely, the notification signal S_{CHG} is at the high voltage level H.

During period T3, the voltage source 112A has finished calibration, and the reference voltage V_{ref} has been updated to the target voltage of the next voltage source to be calibrated. In this case, if the voltage source 112C is the second voltage source to be calibrated next, the reference voltage V_{ref} would be updated to the target voltage 1.8V of the voltage source 112C. In this case, since the BIST circuit 140 has not updated the selection signal S_{CV} yet, the output voltage V_{C} would remain at the voltage V_{CA2} outputted from the voltage source 112A, that is, 1.56V. Since the second fixed voltage difference ΔV₂ is greater than the first fixed voltage difference ΔV₁, that is, the second fixed voltage difference ΔV₂ between the target voltage 1.5V of the voltage source 112A and the target voltage 1.8V of the voltage source 112C is 0.3V, which is greater than the first fixed voltage difference ΔV₁, which is 0.2V. Therefore, the output voltage V_{C} would be smaller than the updated reference voltage V_{ref}, causing the voltage at the output terminal of the first amplifier 120 to change to the low voltage level L.

In addition, since the indication voltage V_{I} would be smaller than the updated reference voltage V_{ref}, the voltage at the output terminal of the second amplifier 132 remains at the low voltage level L, which makes the voltage at the output terminal of the exclusive OR gate 134 to be at the low voltage level L. Namely, the notification signal S_{CHG} would be at the low voltage level L.

In other words, in Table 1 and Table 2, whether the next voltage source to be calibrated is the voltage source 112B or the voltage source 112C, the notification signal S_{CHG} would change from the high voltage level H to the low voltage level L when the reference voltage V_{ref} is updated to the target voltage of the next voltage source to be calibrated, as long as the fixed voltage difference between the target voltages of the voltage sources 112A and 112B and the fixed voltage difference between the target voltages of the voltage sources 112A and 112C are greater than the first fixed voltage difference ΔV₁ between the output voltage V_{C} and the indication voltage V_{I}. Therefore, according to the notification signal S_{CHG}, the BIST circuit 140 can determine whether the reference voltage V_{ref} provided by the external circuit has been updated or not. When the notification signal S_{CHG} changes from the high voltage level H to the low voltage level L, the BIST circuit 140 can update the selection signal S_{CV} to control the voltage output circuit 110 to select the voltage source 112B or 112C to be the second voltage source to be calibrated next.

In some embodiments of the present invention, the voltage output circuit 100 can further include a voltage gap element 150. The voltage gap element 150 is coupled to the voltage output circuit 110 and the first input terminal of the second amplifier 132. The voltage gap element 150 can output the indication voltage V_{I} according to the output voltage V_{C}. In FIG. 1, the voltage gap element 150 is implemented by a transistor M1. The transistor M1 has a first terminal, a second terminal and a third terminal. The first terminal of the transistor M1 receives the output voltage V_{C}, the second terminal of the transistor M1 outputs the indication voltage V_{I}, and the control terminal of the transistor M1 is coupled to the first terminal of the transistor M1. In other words, the transistor M1 can behave as a diode, and the first fixed voltage difference ΔV₁ between the second terminal and the first terminal of the transistor M1 would be the forward voltage of the effective diode of the transistor M1. In some embodiments of the present invention, to meet requirements of different systems, users may choose from different types of transistors, for example, transistor with super low forward voltage. In this case, the voltage output circuit 100 may still function normally even if the voltage differences between the target voltages of the voltage source 112A, 112B and 112C are rather small.

In some embodiments of the present invention, the voltage gap element 150 of the voltage calibration circuit 100 can also be implemented by a diode. The anode of the diode can receive the output voltage V_{C} and the cathode of the diode can output the indication voltage V_{I}.

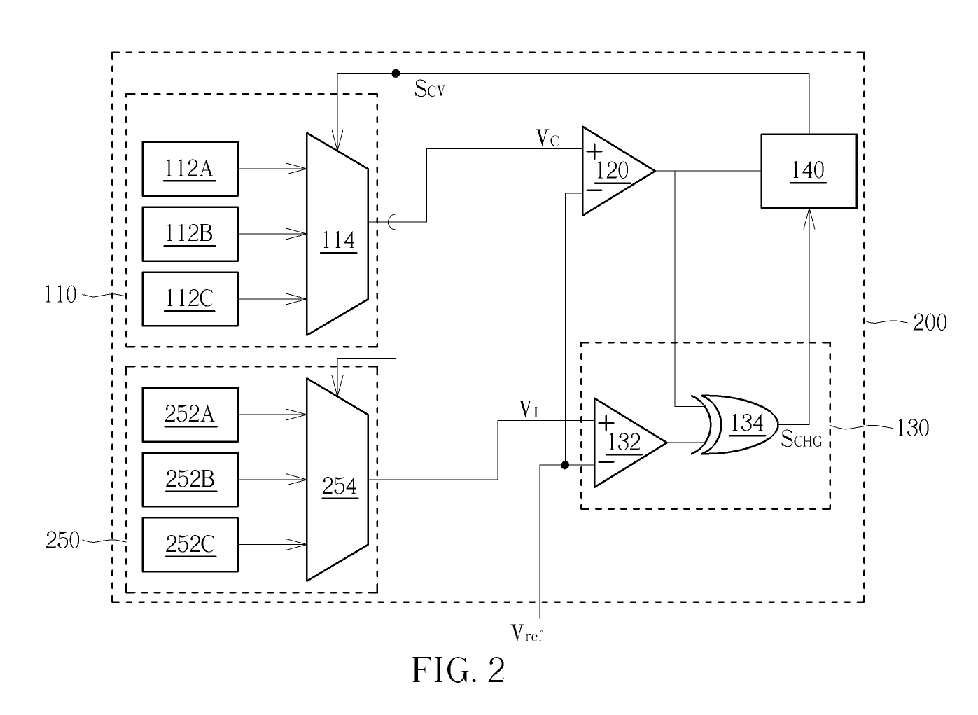

FIG. 2 shows a voltage calibration circuit 200 according to one embodiment of the present invention. The voltage calibration circuits 100 and 200 have similar structures, and the difference is in that the voltage calibration circuit 200 includes an indication voltage output circuit 250. The indication voltage output circuit 250 and the voltage output circuit 110 have similar structures. The indication voltage output circuit 250 includes a plurality of indication voltage sources 252A, 252B, and 252C, and a multiplexer 254. The indication voltage sources 252A, 252B, and 252C are corresponding to the voltage sources 112A, 112B, and 112C respectively. Also, the voltages outputted by the indication voltage sources 252A, 252B, and 252C and the voltages outputted by the corresponding voltage sources 112A, 112B, and 112C have the first fixed voltage difference ΔV₁. The indication voltage output circuit 250 can select a corresponding voltage source from the indication voltage sources 252A, 252B, and 252C to output the indication voltage V_{I} according to the selection signal S_{CV}. For example, when the voltage output circuit 110 selects the voltage source 112A according to the selection signal S_{CV}, the indication voltage output circuit 250 can select the indication voltage source 252A according to the selection signal S_{CV} for outputting the indication voltage V_{I}.

Since the indication voltage output circuit 250 can generate the indication voltage V_{I} by different indication voltage sources 252A, 252B, and 252C, the user may configure the indication voltage output circuit 250 to adjust the value of the first fixed voltage difference ΔV₁ between the indication voltage V_{I} and the output voltage V_{C} according to system requirements, which ensures that the first fixed voltage difference ΔV₁ is smaller than the second fixed voltage difference ΔV₂ and greater than or equal to the third fixed voltage difference ΔV₃. In a better embodiment of the present invention, the third fixed voltage difference ΔV₃ can be substantially equal to the first fixed voltage difference ΔV₁. In this case, the indication voltage sources 252A, 252B, and 252C can have the same structures as the voltage sources 112A, 112B, and 112C, however, the trim codes of the indication voltage sources 252A, 252B, and 252C are one phase behind the trim codes of the voltage sources 112A, 112B, and 112C. For example, during the aforesaid processes, when the voltage source 112A outputs the voltage V_{CA1} at 1.44V according to the trim code, the indication voltage source 252A can use the trim code the voltage source 112A used in a previous phase to output the indication voltage V_{I} at 1.32V. Similarly, when the voltage source 112A outputs the voltage V_{CA2} at 1.56V according to the trim code of next phase, the indication voltage source 252A can use the trim code the voltage source 112A used in a previous phase to output the indication voltage V_{I} at 1.44V. Therefore, the indication voltage sources 252A, 252B, and 252C can have the same structures as the voltage sources 112A, 112B, and 112C, and there is no need to redesign the circuits of the indication voltage sources 252A, 252B, and 252C.

Consequently, the voltage calibration circuit 200 can determine whether the reference voltage V_{ref} provided by the external circuit has been updated or not according to the notification signal S_{CHG}. When the notification signal S_{CHG} changes from the high voltage level H to the low voltage level L, the selection signal S_{CV} is updated so that the voltage output circuit 110 can select the voltage source to be calibrated next accordingly.

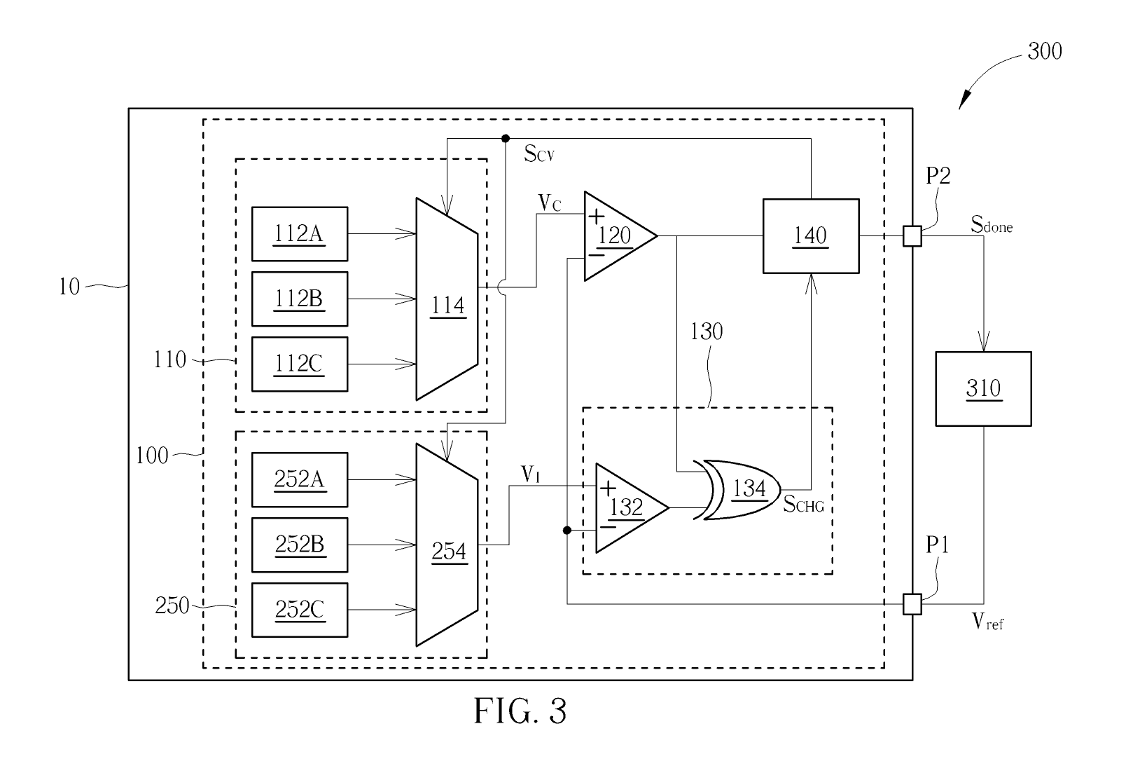

FIG. 3 shows a voltage calibration system 300 according to one embodiment of the present invention. The voltage calibration system 300 includes the voltage calibration circuit 100 and a test circuit 310. The voltage calibration circuit 100 is disposed inside a chip 10. The test circuit 310 is disposed outside the chip 10 and is coupled to the voltage calibration circuit 100 in the chip 10 through pins of the chip 10. That is, the test circuit 310 can provide the reference voltage V_{ref}, for example, the target voltage 1.5V of the voltage source 112A, through a first pin P1 of the chip 10.

After finishing calibration of the voltage source 112A, the BIST circuit 140 can output a completion signal S_{done} through a second pin P2 of the chip 10 to the test circuit 310. In some embodiments of the present invention, the BIST circuit 140 can output a completion signal S_{done} when the voltage at the output terminal of the first amplifier 120 changes from the high voltage level to the low voltage level. The test circuit 310 can adjust the reference voltage V_{ref} according to the completion signal S_{done} so that the adjusted reference V_{ref} voltage will be corresponding to the second voltage source to be calibrate, for example, the voltage source 112B. When the reference voltage V_{ref} is updated to the target voltage 1.2V of the voltage source 112B to be calibrated, the notification circuit 130 would update the notification signal S_{CHG} according to the aforesaid operating principles. Therefore, the voltage calibration circuit 100 can determine whether the reference voltage V_{ref} provided by the test circuit 310 has been updated or not according to the notification signal S_{CHG}. Also, when the notification signal S_{CHG} changes from the high voltage level H to the low voltage level L, the voltage calibration circuit 100 can update the selection signal S_{CV} so that the voltage output circuit 110 can change to select the voltage source 112B for the following calibration process.

In summary, the voltage calibration circuit and the voltage calibration system provided by the embodiments of the present invention can determine whether the reference voltage has been updated or not according to the notification circuit so that the voltage calibration circuit can perform the following calibration process without using external circuits to update the status. Therefore, the issue of big circuit area requirement and the difficulty of wire connection caused by the great number of pins in the prior art can be solved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A voltage calibration circuit, comprising:
a voltage output circuit comprising a plurality of voltage sources to be calibrated, and configured to select a first voltage source from the plurality of voltage sources to output an output voltage to be calibrated according to a selection signal;
a first amplifier having a first input terminal configured to receive the output voltage, a second input terminal configured to receive a reference voltage corresponding to the first voltage source, and an output terminal;
a notification circuit coupled to the output terminal of the first amplifier, and configured to output a notification signal according to an indication voltage, the reference voltage, and a voltage at the output terminal of the first amplifier, wherein the indication voltage and the output voltage have a first fixed voltage difference; and
a built-in self-test circuit coupled to the notification circuit, the first amplifier, and the voltage output circuit, and configured to update the selection signal according to the notification signal so as to enable the voltage output circuit to select a second voltage source from the plurality of voltage sources accordingly.

2. The voltage calibration circuit of claim 1, wherein the notification circuit comprises:
a second amplifier having a first input terminal configured to receive the indication voltage, a second input terminal configured to receive the reference voltage, and an output terminal; and
an exclusive OR gate having a first input terminal coupled to the output terminal of the first amplifier, a second input terminal coupled to the output terminal of the second amplifier, and an output terminal configured to output the notification signal.

3. The voltage calibration circuit of claim 2, wherein the built-in self-test circuit is configured to update the selection signal when the notification signal changes from a high voltage level to a low voltage level.

4. The voltage calibration circuit of claim 3, further comprising:
a voltage gap element coupled to the voltage output circuit and the first input terminal of the second amplifier, and configured to output the indication voltage according to the output voltage.

5. The voltage calibration circuit of claim 4, wherein the voltage gap element is a transistor having a first terminal configured to receive the output voltage, a second terminal configured to output the indication voltage, and a control terminal coupled to the first terminal of the transistor.

6. The voltage calibration circuit of claim 4, wherein the voltage gap element is a diode having an anode configured to receive the output voltage, and a cathode configured to output the indication voltage.

7. The voltage calibration circuit of claim 1, further comprising:
an indication voltage output circuit comprising a plurality of indication voltage sources, the indication voltage output circuit selecting an indication voltage source corresponding to the first voltage source from the plurality of indication voltage sources to output the indication voltage.

8. The voltage calibration circuit of claim 1, wherein a target voltage of the first voltage source and a target voltage of the second voltage source have a second fixed voltage difference, and the second fixed voltage difference is greater than the first fixed voltage difference.

9. The voltage calibration circuit of claim 1, wherein the voltage output circuit further comprises:
a multiplexer coupled to the plurality of voltage sources, and configured to establish an electrical connection between a voltage source of the plurality of voltage sources and an output terminal of the voltage output circuit to output the output voltage.

10. The voltage calibration circuit of claim 9, wherein the first voltage source is configured to output a plurality of output voltages sequentially, and two successive output voltages outputted by the first voltage source have a third fixed voltage difference.

11. The voltage calibration circuit of claim 10, wherein the first fixed voltage difference is greater than or equal to the third fixed voltage difference.

12. A voltage calibration system, comprising:
a voltage calibration circuit comprising:
a voltage output circuit comprising a plurality of voltage sources to be calibrated, and configured to select a first voltage source from the plurality of voltage sources to output an output voltage to be calibrated according to a selection signal;
a first amplifier having a first input terminal configured to receive the output voltage, a second input terminal configured to receive a reference voltage corresponding to the first voltage source, and an output terminal;
a notification circuit coupled to the output terminal of the first amplifier, and configured to output a notification signal according to an indication voltage, the reference voltage, and a voltage at the output terminal of the first amplifier, wherein the indication voltage and the output voltage have a first fixed voltage difference; and
a built-in self-test circuit coupled to the notification circuit, the first amplifier, and the voltage output circuit, and configured to output a completion signal according to the voltage at the output terminal of the first amplifier and update the selection signal according to the notification signal so as to enable the voltage output circuit to select a second voltage source from the plurality of voltage sources accordingly; and
a test circuit configured to provide the reference voltage corresponding to the first voltage source, and adjust the reference voltage according to the completion signal, wherein an adjusted reference voltage is corresponding to the second voltage source.

13. The voltage calibration system of claim 12, wherein the built-in self-test circuit is configured to update the completion signal when the voltage at the output terminal of the first amplifier changes from a high voltage level to a low voltage level.

14. The voltage calibration system of claim 12, wherein the voltage calibration circuit is disposed in a chip, the test circuit provides the reference voltage through a first pin of the chip, and the test circuit receives the completion signal through a second pin of the chip.

15. The voltage calibration system of claim 12, wherein a target voltage of the first voltage source and a target voltage of the second voltage source have a second fixed voltage difference, and the second fixed voltage difference is greater than the first fixed voltage difference.
